(19) United States
(12) Patent Application Publication
(10) Pub. No.: US 2009/0242015 A1
(43) Pub. Date: Oct. 1, 2009

(54) Photovoltaic Roofing Elements, Laminates, Systems and Kits

(76) Inventors: George G. Wattman, Malvern, PA (US); John K. Donaldson, Tampa, FL (US); Gregory F. Jacobs, Oreland, PA (US); Wayne E. Shaw, Glen Mills, PA (US)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 12/414,381

(22) Filed: Mar. 30, 2009

Related U.S. Application Data
(60) Provisional application No. 61/040,376, filed on Mar. 28, 2008.

(51) Int. Cl. H01L 31/048

(52) U.S. Cl. 136/251

(57) ABSTRACT

The present invention relates generally to the photovoltaic generation of electrical energy. The present invention relates more particularly to photovoltaic systems and roofing products for use in photovoltaically generating electrical energy. One aspect of the invention is a photovoltaic roofing element including: a roofing substrate; one or more photovoltaic elements disposed on the roofing substrate; a first electrical terminus and a second electrical terminus, the one or more photovoltaic elements being connected in series between the first electrical terminus and the second electrical terminus; a third electrical terminus and a fourth electrical terminus; and a return electrical path connecting the third electrical terminus to the fourth electrical terminus.

### CROSS-REFERENCE TO RELATED APPLICATIONS

This application claims priority under 35 U.S.C. § 119(e) to U.S. Provisional Patent Application Ser. No. 61/040,376, filed Mar. 28, 2008, which is hereby incorporated herein by reference in its entirety.

### BACKGROUND OF THE INVENTION

1. Field of the Invention

The present invention relates generally to the photovoltaic generation of electrical energy. The present invention relates more particularly to photovoltaic systems and roofing products for use in photovoltaically generating electrical energy.

2. Technical Background

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as system performance has improved. They can be used to provide at least a significant fraction of the electrical energy needed for a building's overall function; or they can be used to power one or more particular devices, such as exterior lighting systems and well pumps.

Accordingly, research and development attention has turned toward integrating photovoltaic cells with roofing products such as shingles, shakes or tiles. A plurality of photovoltaic roofing elements (i.e., including photovoltaic media integrated with a roofing product) can be installed together on a roof, and electrically interconnected to form a photovoltaic roofing system that provides both environmental protection and photovoltaic power generation. Photovoltaic roofing elements are typically electrically interconnected in a series-parallel arrangement, requiring complex wiring systems and/or precise geometrical arrangement of the photovoltaic roofing elements to provide the desired electrical schematic. Accordingly, the flexibility of the numbers or arrangements of photovoltaic roofing elements can be constrained by the geometry and the area of the roof section upon which they are to be installed. These constraints can make system design difficult.

There remains a need for photovoltaic roofing elements and systems that address these deficiencies.

### SUMMARY OF THE INVENTION

One aspect of the invention is a photovoltaic roofing element including:
a roofing substrate;
one or more photovoltaic elements disposed on the roofing substrate;
a first electrical terminus and a second electrical terminus, the one or more photovoltaic elements being connected in series between the first electrical terminus and the second electrical terminus;
a third electrical terminus and a fourth electrical terminus; and
a return electrical path connecting the third electrical terminus to the fourth electrical terminus.

Another aspect of the invention is a photovoltaic roofing array including a plurality of photovoltaic roofing elements as described herein disposed on a roof and connected in series so that the series-connected plurality of photovoltaic elements comprises one or more interior photovoltaic roofing elements and two end photovoltaic roofing elements, so that the first electrical termini of each interior photovoltaic roofing element is connected to the second electrical terminus of an adjacent series-connected photovoltaic roofing element; and the fourth electrical terminus of each interior photovoltaic roofing element is connected to the third electrical terminus of an adjacent series-connected photovoltaic roofing element.

Another aspect of the invention is a photovoltaic roofing system including a plurality of photovoltaic roofing elements as described above, electrically interconnected.

Another aspect of the invention is a kit for the assembly of a photovoltaic roofing system, the kit including a plurality of photovoltaic roofing elements as described herein.

Another aspect of the invention is a photovoltaic laminate including:
a bottom laminate layer;
a top laminate layer;
one or more photovoltaic elements disposed between the top laminate layer and the bottom laminate layer;
a first electrical terminus and a second electrical terminus, the one or more photovoltaic elements being connected in series between the first electrical terminus and the second electrical terminus;
a third electrical terminus and a fourth electrical terminus; and
a return electrical path connecting the third electrical terminus to the fourth electrical terminus.

Another aspect of the invention is a photovoltaic array including a plurality of photovoltaic laminates as described herein connected in series so that the series-connected plurality of photovoltaic laminates comprises one or more interior photovoltaic laminates and two end photovoltaic laminates, so that the first electrical termini of each interior photovoltaic laminate is connected to the second electrical terminus of an adjacent series-connected photovoltaic laminate; and the fourth electrical terminus of each interior photovoltaic laminate is connected to the third electrical terminus of an adjacent series-connected photovoltaic laminate.

Another aspect of the invention is a photovoltaic system including a plurality of photovoltaic laminates as described herein, electrically interconnected.

Another aspect of the invention is a kit for the assembly of a photovoltaic system, the kit including a plurality of photovoltaic laminates as described herein.

The photovoltaic roofing elements, laminates, arrays, systems and kits of the present invention can result in a number of advantages. For example, in certain embodiments, the photovoltaic roofing elements and laminates of the present invention can be arranged in a wide variety of geometrical arrangements, with little regard for electrical system constraints. In certain embodiments, use of the present invention can provide for much simpler electrical interconnection. In certain embodiments, the present invention can provide photovoltaic roofing systems having fewer wires on the roof, improving the aesthetics of the system. Other advantages will be apparent to the person of skill in the art.

The accompanying drawings are not necessarily to scale, and sizes of various elements can be distorted for clarity.

### BRIEF DESCRIPTION OF THE DRAWINGS

FIG. 1 is a top schematic view of a comparative example of a series-interconnected plurality of photovoltaic roofing elements;

FIG. 2 is a top schematic view of a second comparative example of a series-interconnected plurality of photovoltaic roofing elements;

FIG. 3 is a top schematic view of a photovoltaic roofing element according to one embodiment of the present invention;

FIG. 4 is an exploded perspective view of a laminate structure;

FIG. 5 is a top schematic and a side schematic view of a photovoltaic laminate according to one embodiment of the present invention;

FIGS. 6 and 7 are top schematic views of sets of electrically-interconnected photovoltaic roofing elements according to certain embodiments of the present invention;

FIG. 8 is a top schematic view of a photovoltaic roofing system according to one embodiment of the present invention, in which some photovoltaic roofing elements are shown in outline to show detail of underlying photovoltaic roofing elements;

FIG. 9 is a top schematic view and an electrical schematic view of a photovoltaic roofing array according to one embodiment of the present invention, in which the photovoltaic roofing elements are not horizontally arranged; and

FIGS. 10 and 11 are top schematic views and electrical schematic views of photovoltaic roofing systems according to the present invention, in which some photovoltaic roofing elements are shown in outline to show detail of underlying photovoltaic roofing elements.

### DETAILED DESCRIPTION OF THE INVENTION

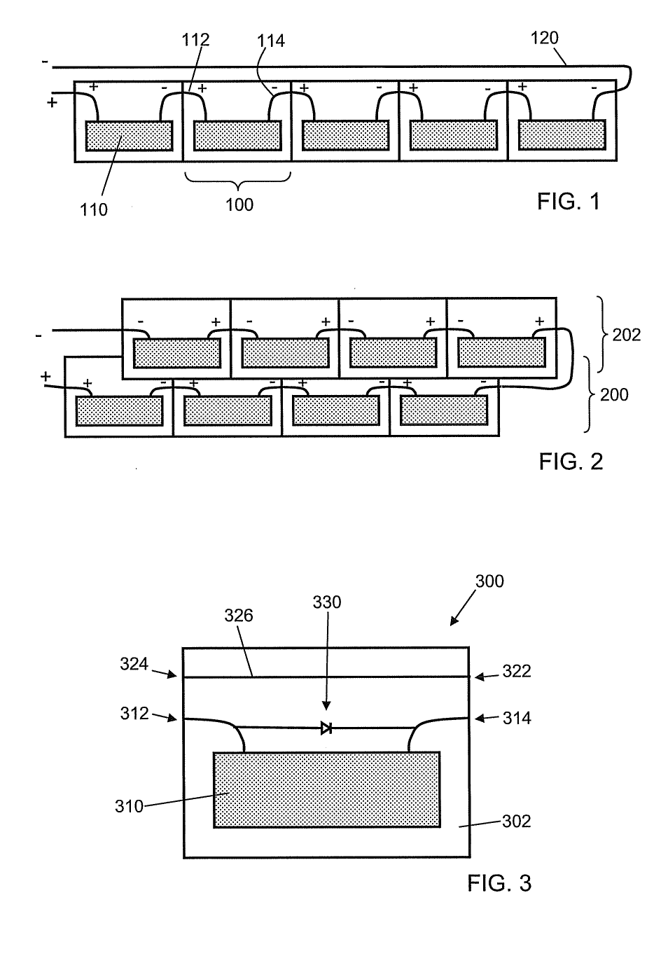

A comparative example of a series-interconnected plurality of photovoltaic roofing elements is shown in top schematic view in FIG. 1. Photovoltaic roofing elements 100, each bearing photovoltaic elements 110, first (positive) electrical terminus 112 and second (negative) electrical terminus 114 are arranged in a single “course” (i.e., a single horizontal row), and connected in series. Voltage builds up from left to right; a connecting wire 120 is necessary to complete the circuit, so that the series-connected photovoltaic roofing elements can be interconnected into an electrical system, for example a “home run” set of cables (i.e., the parallel backbone of a series-parallel wiring system) that routes the photovoltaically-generated power to an inverter for conversion from direct current to alternating current, or to a direct current powered system for local use.

In a second comparative example, shown in top schematic view in FIG. 2, two courses of photovoltaic roofing elements are installed in an overlapping fashion. In the lower course, photovoltaic roofing elements 200 are interconnected so that voltage builds from left to right. The upper course of photovoltaic roofing elements 202 overlays the lower course, with the photovoltaic elements installed so that voltage builds from right to left. While no separate connecting wire is necessary to make a connection to an electrical system at a single point, the number of photovoltaic roofing elements is constrained to be the number in two full courses, which may or may not provide the desired level of voltage buildup from an electrical standpoint. Moreover, in this example, two types of photovoltaic roofing elements are necessary, one having the positive terminus on the left side (e.g., for the lower course), and one having the positive terminus on the right side (e.g., for the upper course).

One embodiment of a photovoltaic roofing element according to the present invention is shown in FIG. 3. Photovoltaic roofing element 300 includes a roofing substrate 302, and one or more photovoltaic elements 310 disposed on the roofing substrate and connected in series between first electrical terminus 312 and second electrical terminus 314. Photovoltaic roofing element 300 also includes a third electrical terminus 322 and a fourth electrical terminus 324, with a return electrical path 326 connecting them. In certain embodiments of the invention, and as shown in FIG. 3, a bypass diode 330 interconnects the first electrical terminus 312 and the second electrical terminus 314 (i.e., in parallel with the one or more photovoltaic elements 310). If the efficiency of the photovoltaic roofing element is diminished, for example by transitory shading, photovoltaic element failure, or some other fault, current passes through the bypass diode, thereby maintaining electrical flow through the system. In certain embodiments, each photovoltaic element of the photovoltaic roofing element has its own bypass diode connected in parallel therewith. While the photovoltaic roofing elements are shown in the FIGS. of this disclosure have one or two photovoltaic elements disposed thereon, the person of skill in the art will appreciate that other numbers of photovoltaic elements can be used.

Photovoltaic elements suitable for use in the various aspects of the present invention include one or more interconnected photovoltaic cells provided together, for example, in a single package. The photovoltaic cells of the photovoltaic elements can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide and copper indium gallium selenide. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of photovoltaic elements for use in the present invention. In one embodiment of the invention, the photovoltaic element includes a monocrystalline silicon photovoltaic cell or a polycrystalline silicon photovoltaic cell. The photovoltaic elements for use in the present invention can be flexible, or alternatively can be rigid.

The photovoltaic elements can be encapsulated photovoltaic elements, in which photovoltaic cells are encapsulated between various layers of material (e.g., as a laminate). For example, a photovoltaic laminate can include a top laminate layer at its top surface, and a bottom laminate layer at its bottom surface. The top laminate layer material can, for example, provide environmental protection to the underlying photovoltaic cells, and any other underlying layers. Examples of suitable materials for the top layer material include fluoropolymers, for example ETFE (“TEFZEL”, or NORTON ETFE), PFE, FEP, PVF (“TEDLAR”), PCTFE or PVDF. The top laminate layer material can alternatively be, for example, a glass sheet, or a non-fluorinated polymeric material (e.g., polypropylene). The bottom laminate layer material can be, for example, a fluoropolymer, for example ETFE (“TEFZEL”, or NORTON ETFE), PFE, FEP, PVDF or PVF (“TEDLAR”). The bottom laminate layer material can alternatively be, for example, a polymeric material (e.g., polyolefin such as polypropylene, polyester such as PET); or a metallic material (e.g., steel or aluminum sheet).

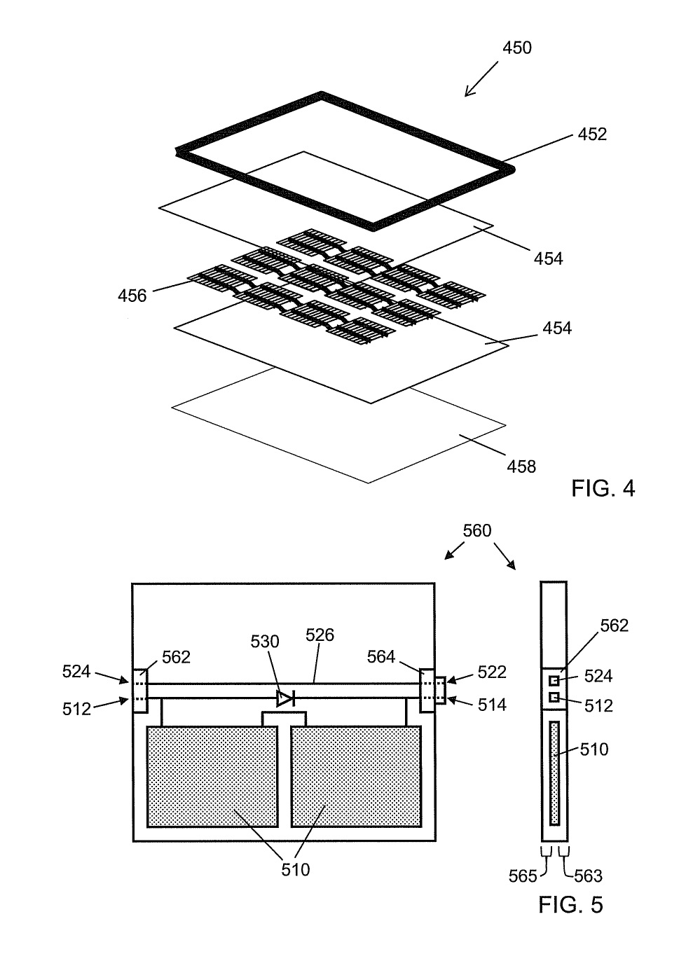

As the person of skill in the art will appreciate, a photovoltaic laminate can include other layers interspersed between the top laminate layer and the bottom laminate layer. For example, a photovoltaic laminate can include structural elements (e.g., a reinforcing layer of glass, metal, glass or polymer fibers, a rigid film, or a flexible film); adhesive layers (e.g., EVA to adhere other layers together); mounting structures (e.g., clips, holes, or tabs); one or more electrical components (e.g., electrodes, electrical connectors; optionally connectorized electrical wires or cables) for electrically interconnecting the photovoltaic cell(s) of the encapsulated photovoltaic element with an electrical system. As described in more detail below, the return electrical path, any series interconnections between photovoltaic elements, and any bypass diodes can be included within the laminate. An example of a photovoltaic laminate suitable for use in the present invention is shown in schematic exploded view FIG. 4. Encapsulated photovoltaic element 450 includes a top protective layer 452 (e.g., glass or a fluoropolymer film such as ETFE, PVDF, PVF, FEP, PFA or PCTFE); encapsulant layers 454 (e.g., EVA, functionalized EVA, crosslinked EVA, silicone, thermoplastic polyurethane, maleic acid-modified polyolefin, ionomer, or ethylene/(meth)acrylic acid copolymer); a layer of electrically-interconnected photovoltaic cells 456 (which can include the return electrical path and bypass diode as described above); and a backing layer 458 (e.g., PVDF, PVF, PET).

The photovoltaic element can include at least one antireflection coating, for example as the top layer material in an encapsulated photovoltaic element, or disposed between the top layer material and the photovoltaic cells. The photovoltaic element can also be made colored, textured, or patterned, for example by using colored, textured or patterned layers in the construction of the photovoltaic element. Methods for adjusting the appearance of photovoltaic elements are described, for example, in U.S. Provisional Patent Applications Ser. No. 61/019,740, and U.S. patent application Ser. Nos. 11/456,200, 11/742,909, 12/145,166, 12/266,481 and 12/267,458 each of which is hereby incorporated herein by reference.

Suitable photovoltaic elements can be obtained, for example, from China Electric Equipment Group of Nanjing, China, as well as from several domestic suppliers such as Uni-Solar Ovonic, Sharp, Shell Solar, BP Solar, USFC, FirstSolar, Ascent Solar, General Electric, Schott Solar, Evergreen Solar and Global Solar. Moreover, the person of skill in the art can fabricate photovoltaic laminates using techniques such as lamination or autoclave processes. Photovoltaic laminates can be made, for example, using methods disclosed in U.S. Pat. No. 5,273,608, which is hereby incorporated herein by reference. Flexible photovoltaic elements are commercially available from Uni-Solar as L-cells having a dimension of approximately 9.5″×14″, S-cells having dimensions of approximately 4.75″×14″, and T-cells having dimensions of approximately 4.75″×7″. Photovoltaic laminates of custom sizes can also be made.

The photovoltaic element also has an operating wavelength range. Solar radiation includes light of wavelengths spanning the near UV, the visible, and the near infrared spectra. As used herein, the term “solar radiation,” when used without further elaboration means radiation in the wavelength range of 300 nm to 2500 nm, inclusive. Different photovoltaic elements have different power generation efficiencies with respect to different parts of the solar spectrum. Amorphous doped silicon is most efficient at visible wavelengths, and polycrystalline doped silicon and monocrystalline doped silicon are most efficient at near-infrared wavelengths. As used herein, the operating wavelength range of a photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. In certain embodiments of the invention, the operating wavelength range of the photovoltaic element falls within the range of about 300 nm to about 1200 nm.

The person of skill in the art will select bypass diode characteristics depending on a number of factors. The characteristics of the diode will depend, for example, on the type and size of photovoltaic element used, the intensity and variability of sunlight expected at the installation location, and the resistance at which a shaded photovoltaic element causes unacceptable system inefficiency. For example, the bypass diode can be configured to bypass a photovoltaic element when its output drops below about 30% of its maximum (i.e., in full sunlight at noon on the solstice) output (i.e., a about 30% or greater degradation in photovoltaically-generated current), below about 50% of its maximum output, below about 70% of its maximum output, below about 90% of its maximum output, or even below about 95% of its maximum output. For example, in one embodiment, in a 20 cell series-connected array of 1 volt/5 amp producing photovoltaic elements, the bypass diodes can be selected to bypass the photovoltaic elements when the output current drops below 4.75 amps (i.e., below 95% of the maximum output). Of course, as the person of skill will appreciate, each system design will have its own set of parameters; with higher amperage systems, relatively more degradation of current can be tolerated. In certain embodiments, the bypass diode can be an 8 amp bypass diode, available from Northern Arizona Wind & Sun, Flagstaff, Ariz.

In other embodiments, the bypass diode can be configured to bypass a photovoltaic element when its resistivity increases by at least about 400% of its resistivity at maximum output, at least about 300% of its resistivity at maximum output, at least about 100% of its resistivity at maximum output, at least about 50% of its resistivity at maximum output, at least about 25% of its resistivity at its maximum output, or even at least about 5% of its resistivity at maximum output.

The present invention can be practiced using any of a number of types of roofing substrates. For example, in one embodiment, the roofing substrate is a rigid roofing substrate. In certain embodiments, such a rigid roofing substrate can take the form of a roofing tile, shake or shingle. In certain embodiments of the invention, the rigid roofing substrate is formed from a polymeric material. Suitable polymers include, for example, polyolefin, polyethylene, polypropylene, ABS, PVC, polycarbonates, nylons, EPDM, TPO, fluoropolymers, silicone, rubbers, thermoplastic elastomers, polyesters, PBT, poly(meth)acrylates, epoxies, and can be filled or unfilled or formed. The rigid roofing substrate can be, for example, a polymeric tile, shake or shingle. The rigid roofing substrate can be made of other materials, such as metallic, composite, clay, ceramic, or cementitious materials. In other embodiments, the roofing substrate is a flexible roofing substrate, for example a bituminous shingle or a plastic shingle. The manufacture of photovoltaic roofing elements using a variety of roofing substrates are described, for example, in U.S. patent application Ser. Nos. 12/146,986, 12/266,409, 12/268,313, 12/351,653, and 12/339,943, and U.S. Patent Application Publication no. 2007/0266562, each of which is hereby incorporated herein by reference in its entirety.

The electrical configuration described above with reference to FIG. 3 can be useful in devices other than the photovoltaic roofing elements described herein. Accordingly, another embodiment of the invention is a photovoltaic laminate, an example of which is shown in top schematic view and cross-sectional schematic view in FIG. 5. Photovoltaic laminate 560 comprises a top laminate layer 563, a bottom laminate layer 565, two photovoltaic elements (e.g., electrically-interconnected sets of photovoltaic cells as described above) 510 disposed between the top laminate layer and the bottom laminate layer. The photovoltaic elements 510 are connected in series between a first electrical terminus 512 and a second electrical terminus 514. A return electrical path 526 connects a third electrical terminus 522 and a fourth electrical terminus 524. As described above with reference to FIG. 3, a bypass diode 530 can interconnect the first electrical terminus 512 and the second electrical terminus 514. In such a laminate, all electrical interconnections can be made within the laminate structure (i.e., between the top and bottom laminate layers).

A photovoltaic laminate of the present invention can be mounted on a roofing substrate to form a photovoltaic roofing element of the present invention. Accordingly, certain photovoltaic roofing elements of the invention comprise a photovoltaic laminate of the present invention mounted on a roofing substrate (e.g., an asphalt shingle)

In certain embodiments of the photovoltaic laminates and photovoltaic roofing elements described herein, electrical connectors can be provided for the interconnection of photovoltaic laminates/roofing elements with one another. For example, as shown in FIG. 5, the first electrical terminus 512 and the fourth electrical terminus 524 can be associated with a first electrical connector 562. Similarly, the second electrical terminus 514 and the third electrical terminus 522 can be associated with a second electrical connector 564. The connectors can, for example, be configured so that a first/fourth electrical terminus connector can mate only with a second/third electrical terminus connector (e.g., using male and female connectors). Of course, connectors need not be used, and the various electrical termini can be provided for example as terminals, or as wires with bared ends.

The return electrical path of the photovoltaic laminates/roofing elements of the present invention can be formed from any suitable electrically conducting material. For example, the return electrical path can be a wire or a strip of metal. In certain embodiments, the return electrical path is a ribbon wire. Use of ribbon wire can be advantageous, in that it can provide a relatively low profile, and therefore will avoid the creation of a hump in the laminate/roofing element structure. When installed on a roof as part of a photovoltaic roofing system, such a structure can provide aesthetic advantages due to the fact that there would be no raised wire structure that could prevent an overlying course of roofing elements from laying flat. The flatter profile can also provide protection of the wiring, as it protrudes far less from the surface of the laminate/roofing element. In certain embodiments, the return wire is embedded in a laminate; in such cases, its location is fixed and known, so that an installer has less of a chance of accidently driving a nail through it.

Moreover, the use of a return electrical path can simplify electrical interconnection of photovoltaic roofing elements and laminates, as the interconnection of adjacent system members will interconnect not only adjacent photovoltaic elements in the forward direction, but will also concominantly create the return path for built-up photovoltaically-generated power. The return electrical path can also enable the use of fewer external wires on the roof, meaning the system designer does not need to account for the position of additional external wires when designing the layout.

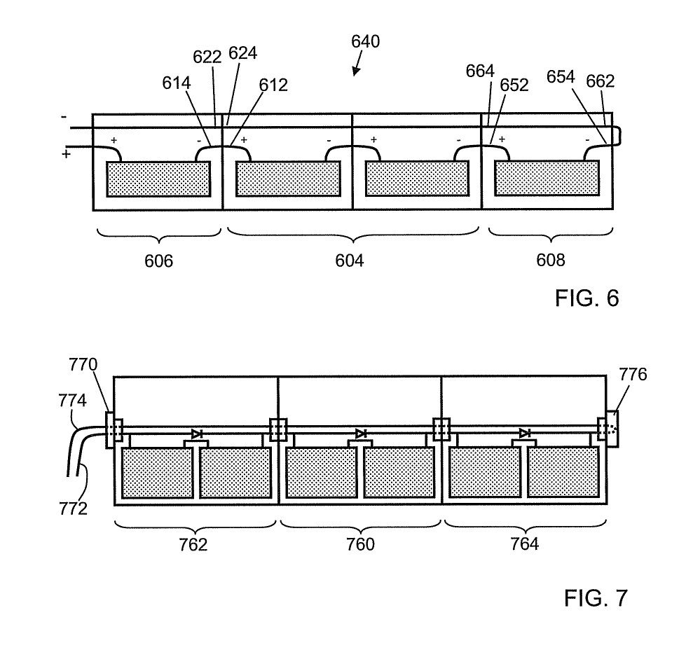

Another embodiment of the invention is a photovoltaic array that includes a plurality of the photovoltaic laminates or roofing elements described herein. For example, an example of a photovoltaic roofing array 640 is shown in top schematic view in FIG. 6. Four photovoltaic roofing elements are interconnected in series, so that the series-interconnected plurality of photovoltaic roofing elements comprises one or more interior photovoltaic roofing elements 604 (in this example, two), a front end photovoltaic roofing element 606, and a rear end photovoltaic roofing element 608. The first electrical terminus 612 of each interior photovoltaic roofing element 604 is connected to the second electrical terminus 614 of an adjacent series connected photovoltaic roofing element, and the fourth electrical terminus 624 of each interior photovoltaic roofing element 604 is connected to the third electrical terminus 622 of the adjacent series-connected photovoltaic roofing element. The first electrical terminus 652 of the rear end photovoltaic roofing element 608 is connected to the second electrical terminus of the adjacent interior photovoltaic roofing element, and the fourth electrical terminus 664 of the rear end photovoltaic roofing element 608 is connected to the third electrical terminus of the adjacent interior photovoltaic roofing element. The second electrical terminus 654 of the rear end photovoltaic roofing element 608 is connected to the third electrical terminus 662 of the rear end photovoltaic roofing element 608. Accordingly, power builds up from left to right along the course of photovoltaic roofing elements, then returns through the return electrical paths to be collected at the front end photovoltaic roofing element. The first electrical terminus and the fourth electrical terminus of the front end photovoltaic roofing element can be connected to a photovoltaic power collection system, e.g., to a home run that leads to an inverter. Connections can be made, for example, using jumper wires or cables, by physically joining exposed wire termini, or using any other suitable method. While the photovoltaic roofing elements of FIG. 6 are shown as being arranged horizontally (i.e., in a single course), in certain advantageous embodiments (as described in more detail below), the photovoltaic roofing elements are not arranged horizontally.

Photovoltaic laminates can be similarly interconnected. For example, a photovoltaic array can be formed from a plurality of photovoltaic laminates as described herein connected in series so that the series-connected plurality of photovoltaic laminates includes one or more interior photovoltaic laminates, a front end photovoltaic laminate, and a rear end photovoltaic laminate. The first electrical terminus of each interior photovoltaic laminate is connected to the second electrical terminus of an adjacent series-connected photovoltaic laminate; and the fourth electrical terminus of each interior photovoltaic laminate is connected to the third electrical terminus of the adjacent series-connected photovoltaic laminate. The first electrical terminus of the rear end photovoltaic laminate is connected to the second electrical terminus of the adjacent interior photovoltaic laminate, and the fourth electrical terminus of the rear end photovoltaic laminate is connected to the third electrical terminus of the adjacent interior photovoltaic laminate. The second electrical terminus of the rear end photovoltaic laminate is connected to its third electrical terminus. Accordingly, power builds up from the front end to the rear end of the series-connected photovoltaic laminates, then returns through the return electrical paths to be collected at the front end photovoltaic laminate. The first electrical terminus and the fourth electrical terminus of the front end photovoltaic laminate can be connected to a photovoltaic power collection system.

As described above, the photovoltaic laminates and photovoltaic roofing elements can include connectors for series interconnection. FIG. 7 provides a top schematic view of a set of series-interconnected photovoltaic laminates 760, 762, 764. In this example, only three photovoltaic laminates are shown in a single course. Of course, a greater number of photovoltaic laminates can be used in a series-interconnected set of photovoltaic laminates, and they need not be disposed in a single course. The photovoltaic laminates are interconnected in series through connectors. A starter connector 770 is connected to front end photovoltaic laminate 762, providing an electrical lead 772 connected to its first electrical terminus, and an electrical lead 774 connected to its fourth electrical terminus. Electrical leads 772 and 774 can be separate (as shown in FIG. 7), or together in a single cable, and can be connectorized at their distal ends for interconnection with an electrical power collection system. A terminator connector 776 is connected to rear end photovoltaic laminate 764, connecting its second electrical terminus to its third electrical terminus, thereby connecting the photovoltaic elements of the photovoltaic laminates to their return electrical paths.

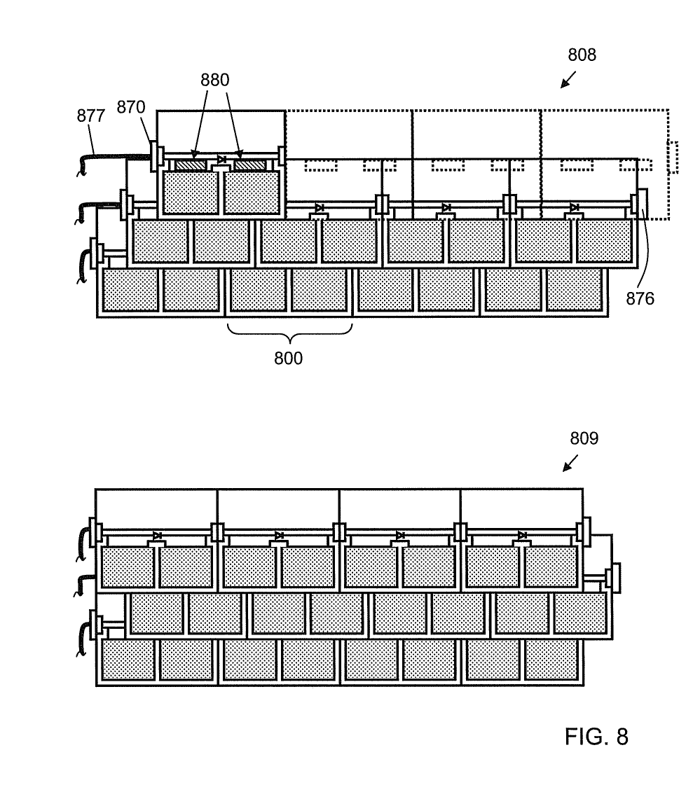

In many embodiments of the invention, the photovoltaic laminates/roofing elements of the present invention will be installed in overlapping courses. FIG. 8 shows a photovoltaic roofing system 808 comprising three offset courses of photovoltaic roofing elements, each of which is formed from a series-interconnected plurality of photovoltaic roofing elements 800. The top course has three photovoltaic roofing elements shown in outline, to reveal the detail of the underlying course. Each course has at its front end a lead connector 870, which has a dual conductor cable 877 for connection to a photovoltaic energy collection system; and at its rear end a terminator connector 876. The photovoltaic roofing elements 800 include fastening zones 880, which include one or more indicia of suitable positions for fasteners, marked on their surfaces. The fastening zones are visible from the top surface of the photovoltaic roofing element. When fasteners (e.g., nails or screws) are driven through the photovoltaic roofing element in the fastening zones, no damage will be caused to the electrical structures of the photovoltaic roofing element (e.g., return electrical path, bypass diodes, interconnections between photovoltaic elements). The fastening zones can be, for example, printed, embossed, or otherwise made visible or indicated on the surface of the photovoltaic laminates/roofing elements. As shown in FIG. 8, in certain embodiments, the fastening zones are located such that an overlying course of photovoltaic laminates/roofing elements will cover them, thereby protecting the heads of the fasteners from the elements. Moreover, in certain embodiments, and as shown by the outlined photovoltaic roofing elements of FIG. 8, the fastening zones can be configured so that the fasteners penetrate and provide additional fastening for underlying photovoltaic roofing elements (i.e., of a lower course), but no damage is done to their electrical structures.

While the photovoltaic roofing system 808 of FIG. 8 is shown as having three courses of four photovoltaic roofing elements each, the person of skill in the art will recognize that actual installations will very often have many more courses and/or photovoltaic laminates/roofing elements per course. Moreover, courses can be offset in different ways, for example, using the stair-step configuration shown in FIG. 8, or using a racked configuration as shown in the photovoltaic roofing system 809 of FIG. 8. In the racked configuration, a second course is installed with a lateral offset to the first, and a third course is installed with a lateral offset reversed relative to the second course, so that it is in vertical alignment with the first course. Of course, other configurations can be used in practicing the present invention.

A further advantage according to one aspect of the invention is in the design flexibility it provides in the coverage of a given area of roof. The configuration of photovoltaic laminates/roofing elements can be adapted to accommodate the geometry and shape of the roof, to avoid any shadowed zones on the roof, and to provide a number of photovoltaic laminates/roofing elements in a series-connected array desirable for adequate power build-up. When using the photovoltaic laminates/roofing elements of the present invention, the system designer is not tightly constrained by the geometric characteristics of a roof surface in designing the electrical schematic of a photovoltaic roofing system. In some systems, it may be desirable (because of the power output of individual photovoltaic laminates/roofing elements) to have arrays of series-interconnected photovoltaic laminates/roofing elements that have a different number of shingles than physically fit along a single course of a roof section. For example, if electrical considerations suggest that each array require groupings of six photovoltaic laminates/photovoltaic elements, but six such units will not fit in a single row on the roof surface, then another configuration is necessary. In other instances, shadowing of a roof may make it undesirable to equip certain portions of the roof with photovoltaic media, and therefore the photovoltaic laminates/photovoltaic elements are to be disposed in an area of irregular shape.

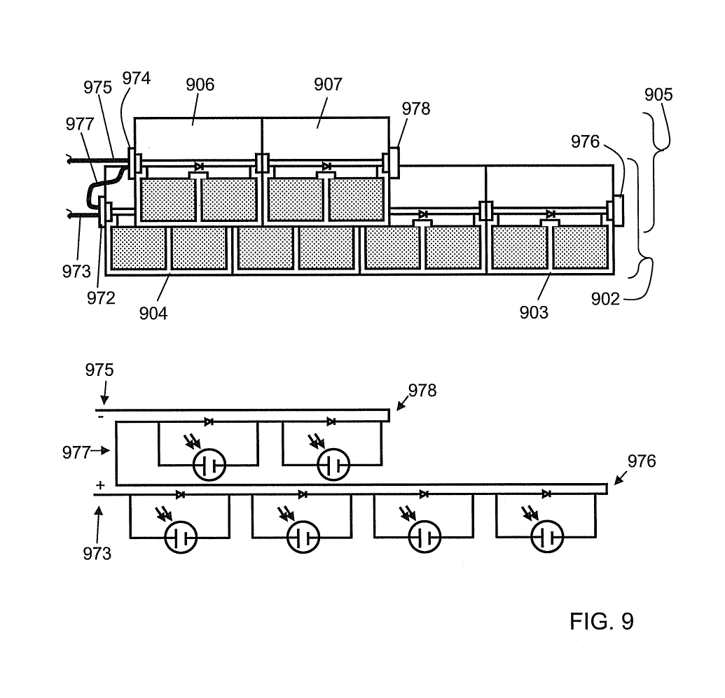

For example, the photovoltaic laminates/roofing elements of the present invention can be arranged in a series-connected set that spans multiple courses. For example, FIG. 9 provides top schematic and electrical schematic views of a photovoltaic array suitable for use as part of a photovoltaic system. FIG. 9 is described for photovoltaic roofing elements; photovoltaic laminates can be similarly arranged. Photovoltaic roofing elements are arranged in a first course 902 and a second course 905. The photovoltaic roofing elements of the first course 902 are interconnected from left to right in series. At the rear end photovoltaic roofing element 903 of the first course 902, terminator connector 976 connects its second and third electrical termini. At the front end photovoltaic roofing element 904 of the first course 902, a lead connector 972 connects a first lead wire 973 to its first electrical terminus, and a jumper wire 977 to its fourth electrical terminus. At the front end photovoltaic roofing element 906 of the second course 905, a lead connector 974 connects jumper wire 977 to its first electrical terminus, and a second lead wire 975 to its fourth electrical terminus. The photovoltaic roofing elements of the second course are interconnected in series from left to right. At the back end photovoltaic roofing element 907 of the second course 905, terminator connector 978 connects its second and third electrical termini. Accordingly, starting at the first lead wire 973, power builds up from left to right along the first course 902 of photovoltaic roofing elements; is routed by the terminator connector 976 back along the return electrical paths of the photovoltaic roofing elements of the first course 902, then to the second course 905 by jumper wire 977; builds up further from left to right along the second course 905; and is routed by the terminator connector 978 back along the return electrical paths of the photovoltaic roofing elements of the second course 905, ultimately to second lead wire 975. First lead wire 973 and second lead wire 975 can be used to connect the array to a home run for the collection of photovoltaically-generated power. The area to the right of the second course of photovoltaic roofing elements can be covered in virtually any desired manner. For example, standard roofing products can be used, as can “dummy” roofing elements (i.e., those looking similar to the photovoltaic roofing elements but having no photovoltaic activity). In certain embodiments, and as described in further detail below, another array of photovoltaic roofing elements can be used to fill in any unused space in the second course.

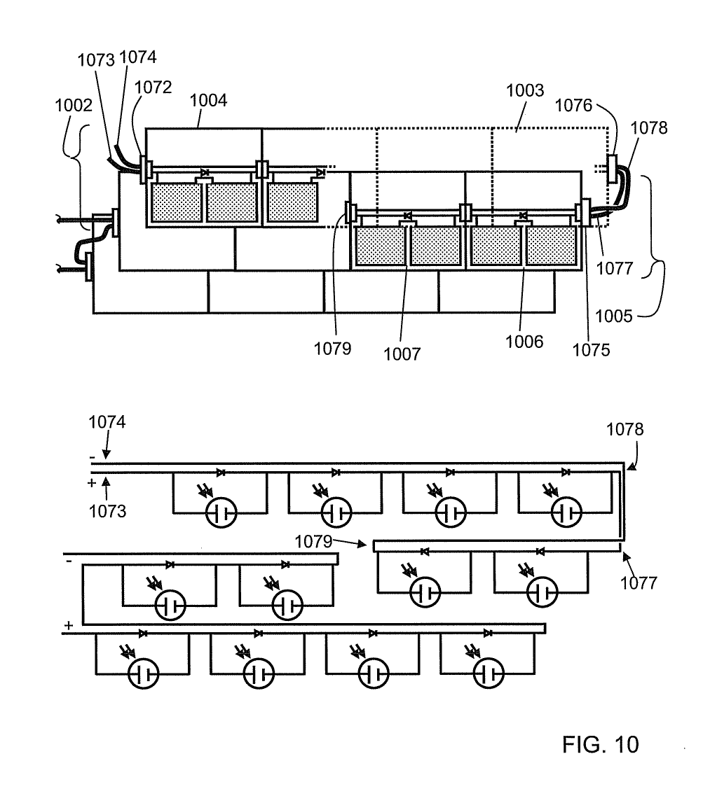

FIG. 10 provides a top schematic view and an electrical schematic view of an embodiment of a photovoltaic system including two photovoltaic arrays, each including a plurality of photovoltaic laminates/roofing elements interconnected in series. FIG. 10 is described for photovoltaic roofing elements; photovoltaic laminates can be similarly arranged. In the photovoltaic roofing system of FIG. 10, the first array is substantially similar to the one described above with respect to FIG. 9, and is not shown in detail in the top schematic view. Like the first array, the second array is provided in two courses, a first (top) course 10 and a second (bottom) course, with the second course disposed horizontally adjacent to the second course of the first array, thus forming a course that is as wide as the other courses in the system. The photovoltaic roofing elements of the first course 1002 are interconnected from left to right in series. At the front end photovoltaic roofing element 1004 of the first course 1002, a lead connector 1072 connects a first lead wire 1073 to its first electrical terminus, and a second lead wire 1074 to its fourth electrical terminus. At the back end photovoltaic roofing element 1003 of the first course 1002, lead connector 1076 connects jumper wire 1077 to its second electrical terminus; and jumper wire 1078 to its third electrical terminus. At the front end photovoltaic roofing element 1006 of the second course 1005, lead connector 1075 connects jumper wire 1077 to its first electrical terminus, and jumper wire 1078 to its fourth electrical terminus. The photovoltaic roofing elements of the second course are interconnected in series from right to left; they are configured to build power in a reverse direction than the photovoltaic roofing elements of the first course. At the back end photovoltaic roofing element 1007 of the second course 1005, terminator connector 1079 connects its second and third electrical termini. While the terminator connectors are shown as protruding from the end of the photovoltaic roofing elements for the sake of clarity, they can be built not to protrude, allowing the terminator connectors of the first array and the second array to fit adjacent to one another without distorting the geometrical arrangement of the photovoltaic roofing elements. Accordingly, starting at the first lead wire 1073, power builds up from left to right along the first course 1002; is routed to the second course through jumper wire 1077; builds up further from right to left along the second course 1005; is routed by the terminator connector 1079 back along the return electrical paths of the photovoltaic roofing elements of the second course 1005, then through jumper wire 1078, and finally back along the return electrical paths of the photovoltaic roofing elements of the first course 1002 to the second lead wire 1074. First lead wire 1073 and second lead wire 1074 can be used to connect the array to a home run for the collection of photovoltaically-generated power.

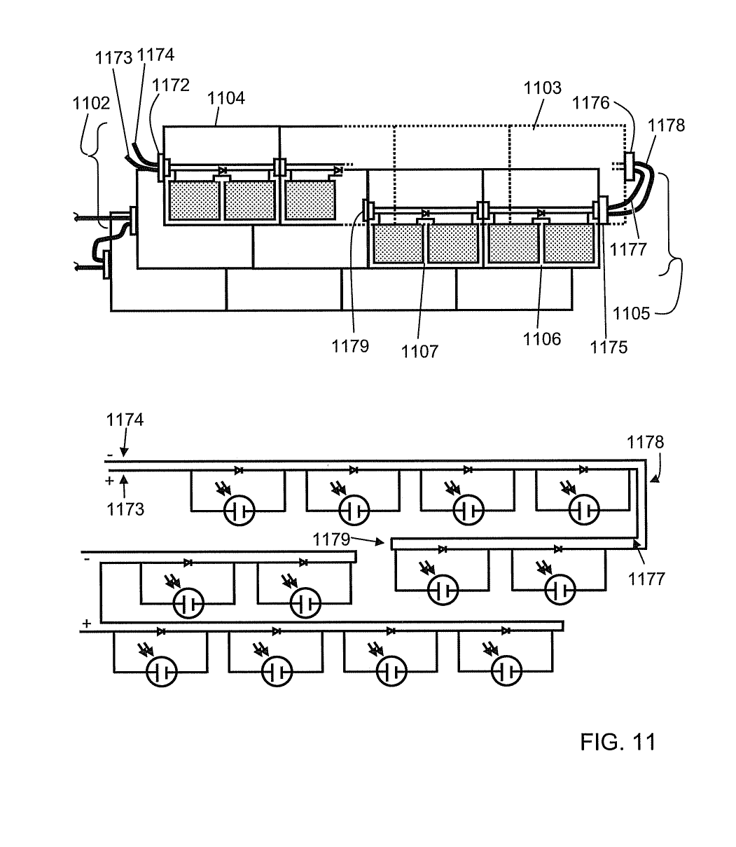

In the embodiment of FIG. 10, the second array includes photovoltaic roofing elements that build power from left to right, as well as photovoltaic roofing elements that build power from right to left. In certain embodiments, it may be undesirable to use two different types of photovoltaic roofing elements. The same geometrical arrangement can be achieved using only a single type of photovoltaic roofing element, for example, as shown in top schematic view and in electrical schematic view in FIG. 11. In the embodiment of FIG. 11, photovoltaic roofing elements of the first course 1102 are interconnected from left to right in series. At the front end photovoltaic roofing element 1104 of the first course 1102, a lead connector 1172 connects a first lead wire 1173 to its first electrical terminus, and a second lead wire 1174 to its fourth electrical terminus. At the back end photovoltaic roofing element 1103 of the first course 1102, terminator connector 1176 connects jumper wire 1177 to its second electrical terminus; and jumper wire 1178 to its third electrical terminus. The photovoltaic roofing elements of the second course are interconnected in series from left to right; they are configured to build power in the same direction as the photovoltaic roofing elements of the first course. At the back end photovoltaic roofing element 1106 of the second course 1105, a lead connector 1175 connects jumper wire 1177 to its third electrical terminus, and jumper wire 1178 to its second electrical terminus. At the front end photovoltaic roofing element 1107 of the second course 1105, terminator connector 1179 connects its first and fourth electrical termini. Accordingly, starting at the first lead wire 1173, power builds up from left to right along the first course 1102; is routed to the second course through jumper wire 1177, then along the return electrical paths of the photovoltaic roofing elements of the second course 1105, then through terminator connector 1179; builds up further from left to right along the second course 1105; is routed through jumper wire 1178, and finally back along the return electrical paths of the photovoltaic roofing elements of the first course 1102 to the second lead wire 1174. First lead wire 1173 and second lead wire 1174 can be used to connect the array to a home run for the collection of photovoltaically-generated power.

Another aspect of the invention is a photovoltaic system including a plurality of photovoltaic laminates/roofing elements as described above, electrically interconnected. The photovoltaic laminates/roofing elements can, for example, be electrically interconnected as described above. Of course, the photovoltaic laminates/roofing elements can also be interconnected in other manners. The photovoltaic system (e.g., a photovoltaic roofing system) can be interconnected with an inverter to allow photovoltaically-generated electrical power to be used on-site, stored in a battery, or introduced to an electrical grid.

Electrical interconnections can be made in a variety of ways in the photovoltaic roofing elements, methods and systems of the present invention. The bypassable photovoltaic elements can be provided with electrical connectors (e.g., available from Tyco International), which can be connected together to provide the desired interconnections. In other embodiments, the bypassable photovoltaic elements can be wired together using lengths of electrical cable. Electrical connections are desirably made using cables, connectors and methods that meet UNDERWRITERS LABORATORIES and NATIONAL ELECTRICAL CODE standards. Electrical connections are described in more detail, for example, in U.S. patent application Ser. Nos. 11/743,073 12/266,498, 12/268,313, 12/359,978 and U.S. Provisional Patent Application Ser. No. 61/121,130 each of which is incorporated herein by reference in its entirety. The wiring system can also include return path wiring (not shown), as described in U.S. Provisional Patent Application Ser. No. 61/040,376, which is hereby incorporated herein by reference in its entirety.

In certain embodiments of the invention a plurality of photovoltaic laminates/roofing elements are disposed on a roof deck and electrically interconnected (e.g., as described above) to form a photovoltaic roofing system. There can be one or more layers of material (e.g. underlayment), between the roof deck and the photovoltaic laminates/roofing elements. The roof can also include one or more standard roofing elements, for example to provide weather protection at the edges of the roof, or in areas not suitable for photovoltaic power generation. In some embodiments, non-photovoltaically-active roofing elements are complementary in appearance or visual aesthetic to the photovoltaic laminates/roofing elements. In certain embodiments, a plurality of photovoltaic laminates of the present invention are electrically interconnected (e.g., as described above) to form a photovoltaic system.

Another aspect of the invention is a kit comprising a plurality of photovoltaic roofing elements of the present invention. Similarly, another aspect is a kit comprising a plurality of photovoltaic laminates of the present invention. The kits can be used for the assembly of photovoltaic arrays and systems as described above. The kit can also include, for example, one or more terminator connectors (i.e., configured to connect the second and third (or first and fourth) electrical termini of a photovoltaic roofing element); one or more lead connectors (configured to connect termini of a photovoltaic roofing element to wire or cable); or both.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents. The specification, drawings and claims of International Application no. PCT/US08/______, entitled “PHOTOVOLTAIC ROOFING ELEMENTS, LAMINATES, SYSTEMS AND KITS” and filed on even date herewith, is hereby incorporated by reference in its entirety.

What is claimed is:

1. A photovoltaic roofing element comprising:
a roofing substrate;
one or more photovoltaic elements disposed on the roofing substrate;
a first electrical terminus and a second electrical terminus, the one or more photovoltaic elements being connected in series between the first electrical terminus and the second electrical terminus;
a third electrical terminus and a fourth electrical terminus; and
a return electrical path connecting the third electrical terminus to the fourth electrical terminus.

2. A photovoltaic roofing element according to claim 1, further comprising a bypass diode connecting the first electrical terminus and the second electrical terminus, the bypass diode being connected in parallel with the one or more photovoltaic elements.

3. A photovoltaic roofing element according to claim 1, wherein the first electrical terminus and the fourth electrical terminus are associated with a first electrical connector.

4. A photovoltaic roofing element according to claim 3, wherein the second electrical terminus and the third electrical terminus are associated with a second electrical connector.

5. A photovoltaic roofing element according to claim 1, wherein the return electrical path is a wire or strip of metal.

6. A photovoltaic roofing element according to claim 1, wherein the return electrical path is a ribbon wire.

7. A photovoltaic roofing element according to claim 1, further comprising one or more fastening zones visible from the top surface of the photovoltaic roofing element, wherein the fastening zones are not in substantial alignment with an electrical component of the photovoltaic roofing element.

8. A photovoltaic roofing element according to claim 1, wherein the roofing substrate is a tile, shake or shingle.

9. A photovoltaic element according to claim 1, wherein the one or more photovoltaic elements and the return electrical path are provided as a photovoltaic laminate in which the photovoltaic elements and the return electrical path are disposed between a top laminate layer and a bottom laminate layer.

10. A photovoltaic roofing array comprising a plurality of photovoltaic roofing elements according to claim 1 disposed on a roof and connected in series so that the series-connected plurality of photovoltaic roofing elements comprises one or more interior photovoltaic roofing elements, a front end photovoltaic roofing element, and a rear end photovoltaic roofing element, so that the first electrical terminus of each interior photovoltaic roofing element is connected to the second electrical terminus of an adjacent series-connected photovoltaic roofing element; and the fourth electrical terminus of each interior photovoltaic roofing element is connected to the third electrical terminus of the adjacent series-connected photovoltaic roofing element.

11. A photovoltaic roofing array according to claim 10, wherein the second electrical terminus of the rear end photovoltaic roofing element is connected to the third electrical terminus of the rear end photovoltaic roofing element.

12. A photovoltaic roofing array according to claim 10, wherein the first electrical terminus and the fourth electrical terminus of the front end photovoltaic roofing element are connected to a photovoltaic power collection system.

13. A photovoltaic roofing system comprising a plurality of photovoltaic roofing elements according to claim 1 disposed on a roof and electrically interconnected.

14. A photovoltaic roofing system comprising a plurality of photovoltaic roofing arrays according to claim 10.

15. A kit for the assembly of a photovoltaic roofing system, the kit comprising a plurality of photovoltaic roofing elements, each photovoltaic roofing element comprising a roofing substrate;
one or more photovoltaic elements disposed on the roofing substrate;
a first electrical terminus and a second electrical terminus, the one or more photovoltaic elements being connected in series between the first electrical terminus and the second electrical terminus;
a third electrical terminus and a fourth electrical terminus; and
a return electrical path connecting the third electrical terminus to the fourth electrical terminus.

16. A kit according to claim 15, further comprising one or more terminator connectors, one or more lead connectors, or both.

17. A photovoltaic laminate including:
a bottom laminate layer;
a top laminate layer;
one or more photovoltaic elements disposed between the top laminate layer and the bottom laminate layer;
a first electrical terminus and a second electrical terminus, the one or more photovoltaic elements being connected in series between the first electrical terminus and the second electrical terminus;
a third electrical terminus and a fourth electrical terminus; and
a return electrical path disposed between the top laminate layer and the bottom laminate layer, connecting the third electrical terminus to the fourth electrical terminus.

18. A photovoltaic laminate according to claim 17, further comprising a bypass diode disposed between the top laminate layer and the bottom laminate layer and connecting the first electrical terminus and the second electrical terminus, the bypass diode being connected in parallel with the one or more photovoltaic elements.

19. A photovoltaic laminate according to claim 17, wherein the return electrical path is a wire or strip of metal.

20. A photovoltaic array comprising a plurality of photovoltaic laminates according to claim 17 connected in series so that the series-connected plurality of photovoltaic laminates comprises one or more interior photovoltaic laminates, a front end photovoltaic laminate, and a rear end photovoltaic laminate, so that the first electrical terminus of each interior photovoltaic laminate is connected to the second electrical terminus of an adjacent series-connected photovoltaic laminate; and the fourth electrical terminus of each interior photovoltaic laminate is connected to the third electrical terminus of the adjacent series-connected photovoltaic laminate.

21. A photovoltaic system comprising a plurality of photovoltaic laminates according to claim 17, electrically interconnected.

22. A kit for the assembly of a photovoltaic system, the kit comprising
a plurality of photovoltaic laminates according to claim 17.
